(19) United States
(12) Patent Application Publication
(10) Pub. No.: US 2008/0157800 A1
(43) Pub. Date: Jul. 3, 2008

(54) TEG pattern and method for testing semiconductor device using the same

(75) Inventor: Ji Ho Hong, Ilwaseong-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/881,647

(22) Filed: Jul. 27, 2007

(30) Foreign Application Priority Data
Dec. 27, 2006 (KR) 10-2006-0135771

(51) Int. Cl. G01R 31/02; H01L 23/58

(52) U.S. Cl. 324/763; 257/48; 257/E23.001

(57) ABSTRACT

A TEG pattern comprises: a plurality of device isolation layer patterns having a predetermined gap; an active area pattern between adjacent device isolation layer patterns; and metal 1 contact patterns in the active region pattern.

The present application claims priority under 35 U.S.C. 119 and 35 U.S.C. 365 to Korean Patent Application No. 10-2006-135771 (filed on Dec. 27, 2006), which is hereby incorporated by reference in its entirety.

### BACKGROUND

1. Field of the Invention

The invention relates to a TEG pattern (Test Element Group pattern) and a method for testing a semiconductor device using the same.

2. Description of the Related Art

In order to confirm whether the progressing results of the respective processes in a semiconductor manufacturing process are acceptable or preferable, the thickness, resistance, concentration, degree of contamination, critical dimensions, and electrical characteristics of devices or structures therein should be measured. In such a measurement process, the wafer of the semiconductor device may be damaged. As a result, one may be incapable of monitoring characteristics of an actual wafer in process (e.g., during the manufacturing process or between steps of the process, while the wafer is still in the manufacturing fab).

In such a case, the corresponding processes or device characteristics are evaluated by measuring the TEG pattern after forming a pattern called a TEG (Test Element Group) on a specific portion of the wafer or on a separate blank wafer and performing the processes under the same conditions as the processes performed on the actual device wafer. Such a wafer is referred to as a monitor wafer or a test wafer.

There are several important TEG patterns in developing the semiconductor device. However, the most important thing among them is a TEG pattern made under the same conditions as an actual memory cell called a defect cell array. Such a TEG pattern is approximately the same structure as the memory cell of the actual device wafer. In the case of changing a design rule or materials used in the memory cell, in order to confirm short or open defects internally caused by connecting the respective conductive layers to the outside, the reliability, stability, and process margin, and the like are evaluated by measuring the resistance or capacitance of TEG pattern, etc.

However, when a contact lands on a source/drain area (e.g., an active area) in a 90 nm technology node or less, very tight control of overlay misalignment is relatively more important than in larger technology nodes.

However, the related art may not sufficiently control a margin for the overlay misalignment in 90 nm technology node or less, thereby leading to a possible increase in leakage current.

Also, diode leakage according to an ion implant process condition in a PN junction diode area between the source/drain area and a well area may have a large effect on the characteristics of the semiconductor device. Consequently, it should be very carefully considered in a process having a minimum design rule of 90 nm or less.

However, in manufacturing the semiconductor device on a 90 nm tech node or less according to the related art, an electric test module, which can effectively monitor the degree of overlay misalignment of a metal 1 contact (M1C) in the active area, and a test module, which can accurately monitor the leakage characteristics of the PN junction diode area, may not have systemically been developed.

In particular, an active extension for the metal interconnect to the metal 1 contact (M1C) pattern is the design rule that is advantageously carefully established in view of such current leakage data, and in actual practice, the concrete numerical values thereof should be determined by silicon (Si) substrate data fed back from a proper and/or effective TEG.

### SUMMARY OF THE INVENTION

Embodiments of the present invention provide a TEG pattern and a method for testing a semiconductor device capable of confirming a level of leakage current caused by misalignment in an active area of a metal 1 contact (M1C) through silicon (Si) substrate data (e.g., from the point of view of an active extension design rule for the M1C), in manufacturing a semiconductor device having a 90 nm minimum design rule or less.

Also, embodiments of the present invention provide a TEG pattern and a method for testing a semiconductor device capable of monitoring the characteristics of current leakage up to electrically fine levels in a PN junction diode area that is closely related to ion implant process conditions.

Also, the embodiments of the present invention provide a TEG pattern and a method for testing a semiconductor device capable of improving the yield of the semiconductor device and promoting the efficiency of the development thereof through a newly devised two-terminal TEG.

A TEG pattern according to embodiments of the present invention comprises a device isolation layer pattern having a predetermined gap between adjacent active areas; an active area pattern in the device isolation layer pattern; and a contact pattern (e.g., a metal 1 contact [M1C] pattern) in the active region pattern.

Also, A TEG pattern according to embodiments of the present invention may comprise a well pick-up area including a plurality of island type diode TEGs; a metal strap area electrically connected to the plurality of island type diode TEGs; a first metal pad applying a potential to the metal strap area; and a second metal pad detecting leakage current from the well pick-up area as a result of the potential applied by the first metal pad.

Also, a method for testing a semiconductor device according to embodiments of the present invention comprises monitoring leakage current as a function of the dimensional difference between an active area pattern and a contact pattern thereto using a TEG pattern including a device isolation layer pattern having a predetermined gap between adjacent active areas, an active area pattern in the device isolation layer pattern, and a contact pattern to the active region pattern.

Also, a method for testing a semiconductor device may comprise the steps of: applying a potential to a metal strap area including a plurality of island type diode TEGs from a lower metal pad; and detecting leakage current from a well pick-up area to an upper metal pad as a result of the potential applied by the lower metal pad.

### BRIEF DESCRIPTION OF THE DRAWINGS

FIG. 1 is a layout of a TEG pattern according to an embodiment of the present invention;

FIGS. 2 to 4 are enlarged layouts of the TEG pattern according to further embodiments of the present invention; and

FIG. 6 is a cross-sectional view of the TEG pattern according to an embodiment of the present invention.

### DETAILED DESCRIPTION OF THE EMBODIMENTS

Hereinafter, an embodiment of a TEG (Test Element Group) pattern and a method for testing a semiconductor device using the same will be described with reference to the accompanying drawings.

In the description of the embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

### First Embodiment

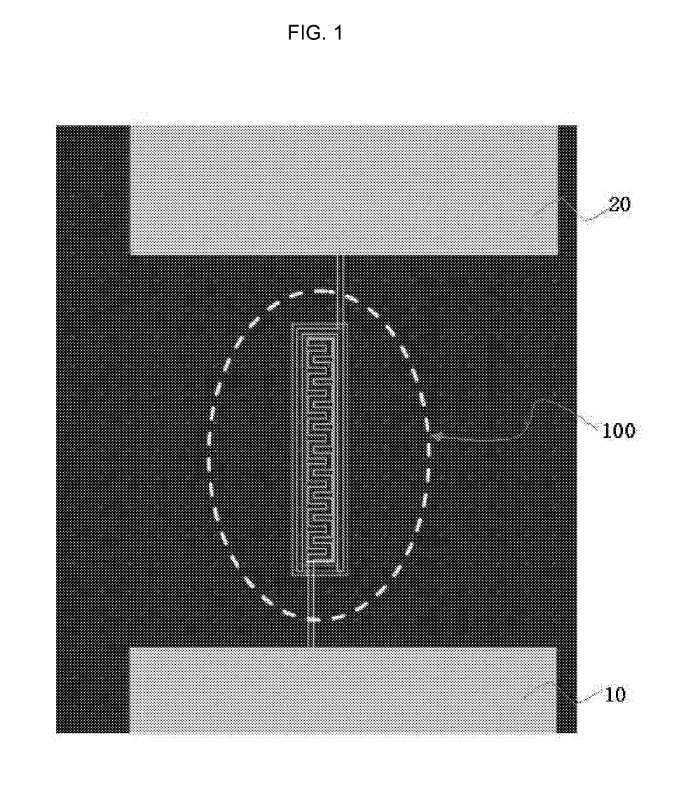

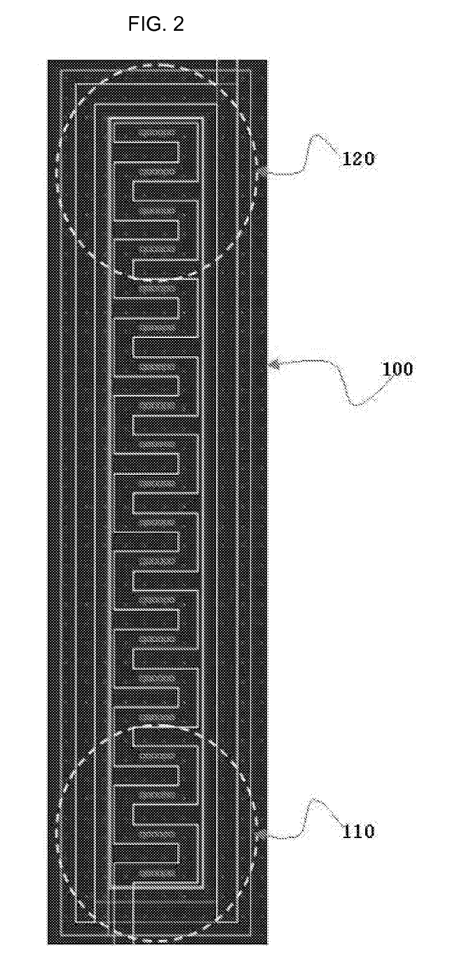

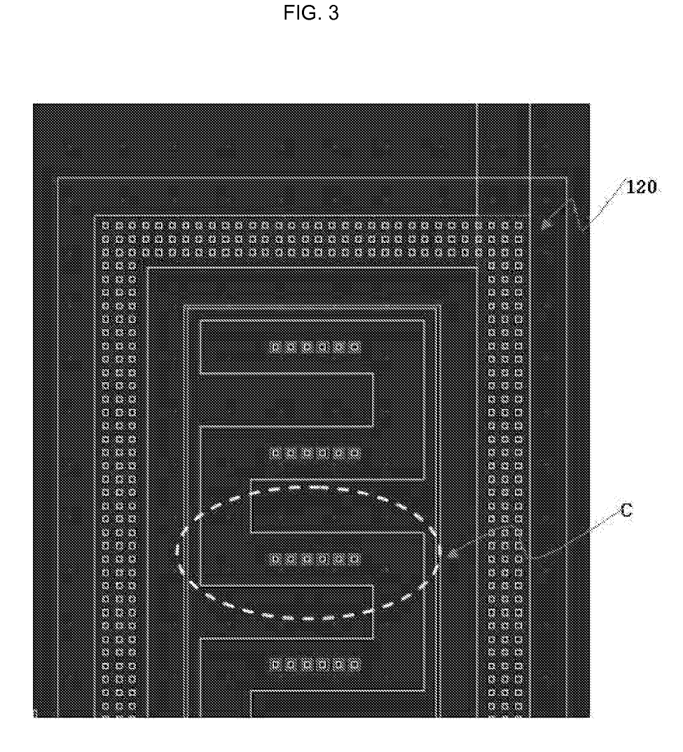

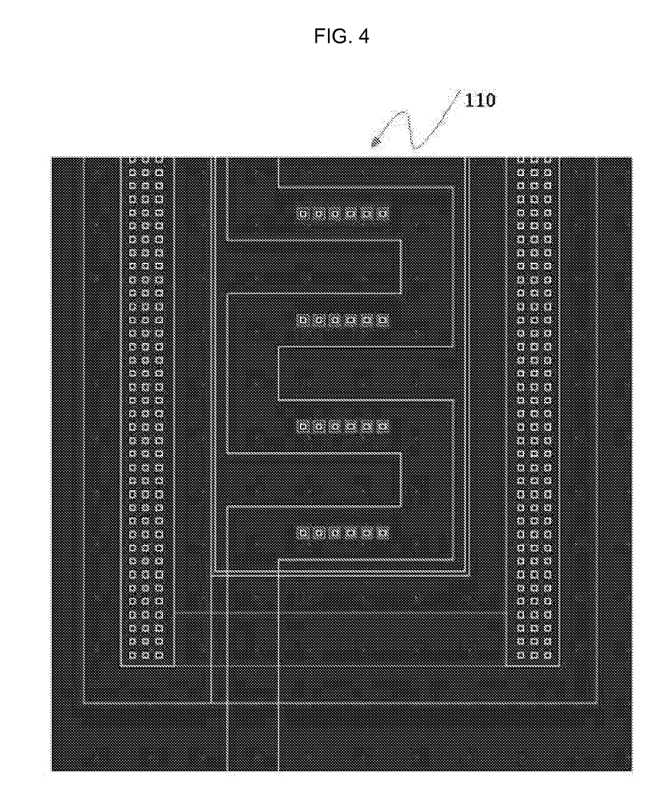

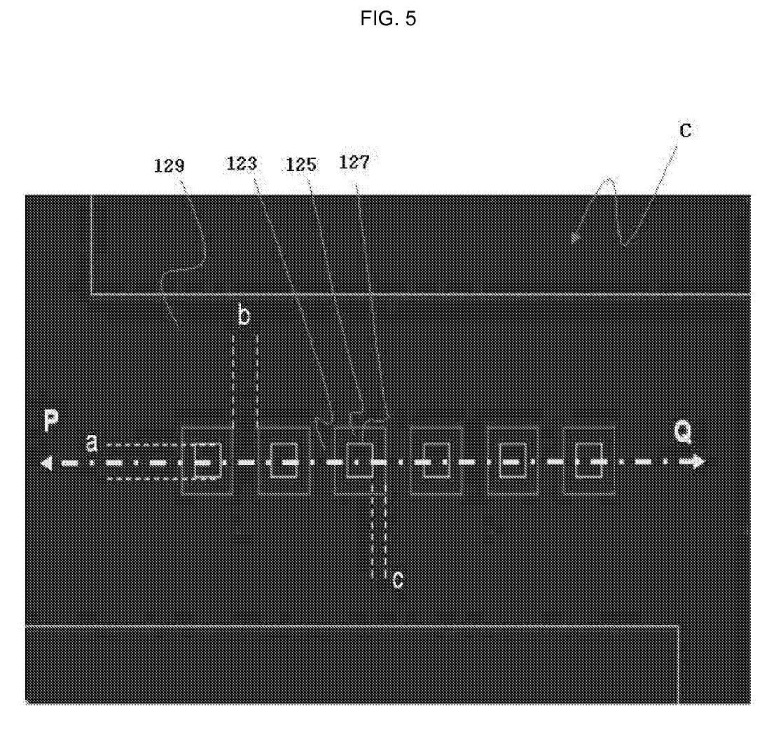

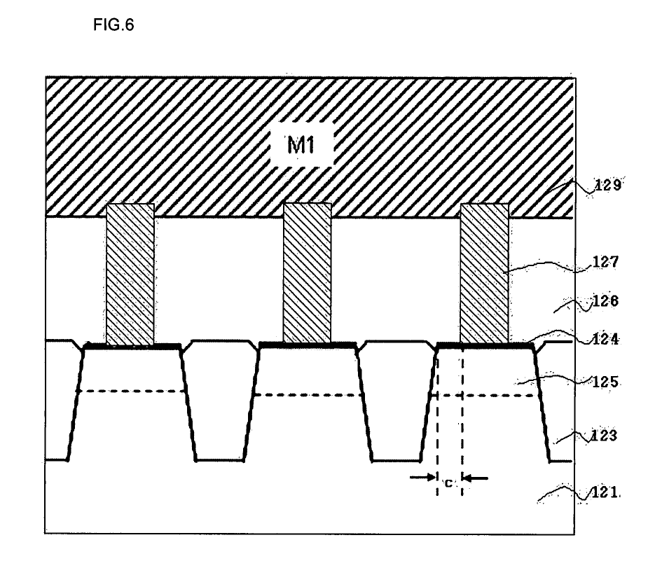

FIG. 1 is a layout of a TEG pattern according an embodiment of the present invention. FIG. 2 is an enlarged layout of the TEG pattern, and FIGS. 3 and 4 are each an enlarged layout showing a well pick-up area 120 and a metal strap area 110, respectively. FIG. 5 is an enlarged layout of a TEG pattern (C) in the well pick-up area 120 shown in FIG. 3, and FIG. 6 is a cross-sectional view taken along line PQ of the layout shown in FIG. 5.

As shown in FIGS. 1 and 2, the TEG pattern 100 according to a first embodiment comprises a well pick-up area 120 including a plurality of island type diode TEGs; a metal strap area 110 including the plurality of island type diode TEGs; a first or lower metal pad 10 applying a potential to the metal strap area 110; and a second or upper metal pad 20 detecting leakage current from the well pick-up area 120 as a result of the potential applied by the lower metal pad 10.

In particular, in manufacturing the semiconductor device, the present TEG pattern is capable of confirming a level of leakage current caused by a misaligned metal 1 contact (M1C) pattern to an active area in a silicon (Si) substrate, and providing such leakage current data from the point of view of an active extension design rule for the metal 1 contact (M1C) pattern.

To this end, as shown in FIGS. 5 and 6, the island type diode TEGs 120 and 130 comprise a device isolation layer pattern 123; a plurality of active areas 125 (e.g., an active area pattern) in the device isolation layer pattern 123, and a plurality of metal 1 contacts 127 (e.g., a contact pattern) in the active areas 125.

An “island type diode TEG” may refer to one of a plurality of diode TEGs, where each of the plurality of TEG diodes is divided from each other multiple times, like a chain of islands. The TEG pattern can be formed on the well-pattern 121 as shown in FIG. 6, and the metal 1 contact pattern (which may comprise a plurality of contacts 127) can be formed in a dielectric layer 128 (e.g., an interlayer dielectric layer pattern). Also, between the active areas in pattern 125 and the contacts in metal 1 contact pattern 127 can further be formed a silicide pattern or layer 124.

Here, as shown in FIG. 5, the device isolation layer pattern 123 and the metal 1 contact pattern 127 may have one or more dimensions that are at or above the numeral values of a minimum design rule in the related art (e.g., about 90 nm in a 90 nm manufacturing technology). For example, in one case, the device isolation layer pattern 123 and the metal 1 contact pattern 127 can have one or more dimensions or spacings equal to the value of the minimum design rule of the manufacturing technology (e.g., 90 nm in a 90 nm manufacturing technology. On the other hand, the size or dimension (b) of the device isolation layer pattern 123 (i.e., the space between adjacent active areas 125) and the size or dimension (a) of the metal 1 contact pattern 127 can be greater than the value of the minimum design rule, so that it minimizes or does not cause any patterning problems. However, when the size or dimension (b) of the device isolation layer pattern 123 and the size or dimension (a) of the metal 1 contact pattern 127 is equal to the value of the minimum design rule, the most precise monitoring of leakage current can be made. In other words, the TEG pattern 100 according to embodiments of the invention can monitor the leakage current according to the distance (c) (e.g., the difference between a width and/or length) of the active area pattern 125 and the metal 1 contact pattern 127. Thus, the TEG pattern 100 may comprise one or more first device isolation layer patterns 123 and one or more first contact patterns 127 having dimensions greater than a minimum design rule, and a second device isolation layer pattern 123 and a first contact pattern 127 having one or more dimensions equal to a minimum design rule. In addition, each TEG pattern 100 according to the invention may be located in a test die on a wafer, a test area of a die, or in a scribe lane of a wafer. At this time, the distance (c) of the active area pattern 125 not covered by the metal 1 contact pattern 127 can be 200 nm or less.

For example, the leakage current can be monitored by splitting or varying the distance (c) of the active area pattern 125 and the metal 1 contact pattern 127, from a maximum (e.g., 200 nm or less), to a minimum, decreasing the distance difference by predetermined incremental units (e.g., 10 nm gaps), making it possible to obtain an optimal design rule by using the monitored feedback (leakage current) data. In order words, the distance difference (c) between the active area pattern 125 and the metal 1 contact pattern 127 may vary in increments from 0 nm up to 200 nm (e.g., 0 nm, 10 nm, 20 nm, 30 nm, etc., up to 200 nm), and the leakage current is monitored according to the distance or dimension (c) of the respective active area pattern 125 and metal 1 contact pattern 127, making it possible to obtain an optimal design rule using the monitored leakage current data.

At this time, the leakage current can be monitored by splitting or incrementally varying the distance (c) (i.e., the difference between the length and/or width) of the active area pattern 125 and the metal 1 contact pattern 127 (which can be as high as 200 nm or less, 150 nm or less, or 100 nm or less) by difference increments (e.g., of 2.5 nm, 5 nm, 10 nm, 12 nm, 15 nm, 20 nm, etc.); however, it is not limited thereto. Accordingly, the maximum distance can be set to the size of the active area pattern 125 and the variance increment can be set according to various distance differences.

Also, the TEG pattern 100 may include about 100 or more of the island type diode TEGs, which are preferably constant in the distance (C) of the active area pattern 125 and the metal 1 contact pattern 127.

Although the present TEG pattern 100 may include a hundred of the island type diodes, the number may be 100 or more or less than 100. However, as the number of the island type diodes increases, a finer level of leakage current can be detected (i.e., the leakage current can be determined with an increased sensitivity and/or granularity).

The present island type diode TEG module design is also capable of monitoring the characteristics of current leakage in a PN junction diode area that is closely related with ion implant process conditions. Such monitoring can be performed up to an electrically fine level, as discussed in the preceding paragraph.

Hereinafter, a method for testing a semiconductor manufacturing process and/or semiconductor device using the present TEG pattern is described.

First, referring to FIGS. 1-2, a potential is applied from a first (or lower) metal pad 10 to the metal strap area 110, which is electrically connected to the plurality of island diode TEGs via the contacts in the contact pattern 127 (see FIGS. 5-6). Thereafter, the leakage current from the well pick-up area 120 to the second (or upper) metal pad 20 is detected by electrodes in electrical communication with the second metal pad 20 (i.e., as a result of the potential applied by the lower metal pad 10 to the plurality of island diode TEGs).

At this time, the TEG pattern 100 comprises the device isolation layer pattern 123 having a predetermined gap between adjacent active areas, the active areas 125 in the device isolation pattern 123, and the metal 1 contact patterns 127 formed in the active area patterns 125. The active areas 125 in well 121 constitute the island type diodes in the TEG pattern 100.

The method for testing the semiconductor manufacturing process and/or semiconductor device according to embodiments of the invention monitors the leakage current according to variance(s) in the distance (c) of the active area pattern 125 (i.e., the difference between the width and/or length of the active area 125 and the contact 127 formed thereto). Here, the device isolation layer pattern 123 and the metal 1 contact pattern 127 have dimensions above the value of the minimum design rule for the manufacturing technology.

The method for testing the semiconductor device according to embodiments of the invention can detect the level of leakage current very precisely by incrementally varying an extension distance from the metal 1 contact (M1C) to the edge of the active area 125. When the number of the island type diodes included in the metal strip area 110 (and, preferably, elsewhere throughout the TEG pattern 100) are constantly maintained as shown in FIGS. 1 and 2, reliable leakage current results can be obtained for the process.

In one example, an embodiment of the invention employs a hundred or more of the island type diodes. However, as the number of the island type diodes is increased, a finer level of leakage current can be detected. For example, the method may monitor the leakage current by varying the distance or dimension difference (c) of the active area pattern 125 and the metal 1 contact pattern 127 from a maximum of 200 nm or less to a minimum (e.g., of about 0 nm or 10 nm) by, e.g., 10 nm gaps; however, it is not limited thereto. Accordingly, the maximum distance (c) can be set to the size of the active area 125 minus the minimum size of the contact 127, and the variation increments can be set according to various distance differences. Also, with the invention, an accurate active extension design rule for the metal 1 contact (M1C) 127 can be determined from silicon data (Si data) obtained from the TEG pattern 100.

As described above, the present TEG pattern and method for testing a semiconductor manufacturing process and/or device using the same is capable of confirming the level of leakage current caused by misaligned metal 1 contacts (M1C) through the silicon (Si) substrate data from the point of view of the active extension design rule for the (M1C), for example in manufacturing semiconductor devices having a minimum design rule of 90 nm or less.

Also, the present island type diode TEG module design is capable of monitoring the characteristics of current leakage in the PN junction diode area (that is, in turn, closely related with the ion implant process conditions) effectively up to an electrically fine level.

Also, the quality (e.g., any degradation in properties or characteristics) of the semiconductor device due to the occurrence of leakage current in manufacturing the semiconductor device can be monitored through the newly devised two-terminal TEG, and the active extension design rule for the M1C can accurately be determined from the silicon data (Si data) obtained from the TEG so that the manufacturing yield of the semiconductor device can be improved and the manufacturing cost thereof can be reduced as a whole.

Any reference in this specification to “one embodiment,” “an embodiment,” “example embodiment,” etc., means that a particular feature, structure, or characteristic described in connection with the embodiment is included in at least one embodiment of the invention. The appearance of such phrases in various places in the specification is not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A test element group (TEG) pattern comprising:
a device isolation layer pattern having a predetermined gap between adjacent active areas;
an active area pattern in the device isolation layer pattern; and
a contact pattern in the active region pattern.

2. The TEG pattern according to claim 1, wherein the device isolation layer pattern and the contact pattern have dimensions above the value of a minimum design rule.

3. The TEG pattern according to claim 2, further comprising a second device isolation layer pattern and a second contact pattern having a dimension equal to a minimum design rule.

4. The TEG pattern according to claim 2, configured to monitor leakage current according to a difference in a dimension of the active area pattern and the 1 contact pattern.

5. The TEG pattern according to claim 4, wherein the difference in the dimension of the active area pattern and the contact pattern is 200 nm or less.

6. The TEG pattern according to claim 3, comprising a plurality of device isolation layer patterns and contact patterns, wherein a difference in a dimension of the active area patterns and the contact patterns varies from a maximum of 200 nm or less.

7. The TEG pattern according to claim 1, wherein the contact pattern provides one contact to each active region in the active region pattern.

8. A test element group (TEG) pattern comprising:
a well pick-up area including a plurality of island type diode TEGs;
a metal strap area electrically connected to contacts to the plurality of island type diode TEGs;
a first metal pad applying a potential to the metal strap area; and
a second metal pad configured to detect leakage current from the well pick-up area as a result of the potential applied by the first metal pad.

9. The TEG pattern according to claim 8, wherein each of the island type diode TEGs comprise:
a device isolation layer pattern having a predetermined gap between adjacent active areas;
an active area pattern in the device isolation layer pattern; and
a contact pattern in the active region pattern.

10. The TEG pattern according to claim 9, further comprising one or more second device isolation layer patterns and one or more second contact patterns having dimensions above the value of a minimum design rule.

11. The TEG pattern according to claim 10, wherein the device isolation layer pattern and the contact pattern have dimensions equal to the numeral values of a minimum design rule.

12. The TEG pattern according to claim 9, configured to monitor leakage current according to a difference in a dimension of the active area pattern and the contact pattern.

13. The TEG pattern according to claim 12, wherein the difference in the dimension of the active area pattern and the contact pattern is 200 nm or less.

14. The TEG pattern according to claim 9, wherein the contact pattern provides one contact to each active region in the active region pattern.

15. A method for testing a semiconductor device comprising the steps of:
applying a potential to a metal strap area electrically connected to a plurality of island type diode test element groups (TEGs) from a first metal pad; and
detecting leakage current from a well pick-up area of the plurality of island type diode TEGs to a second metal pad as a result of the potential from the first metal pad.

16. The method according to claim 15, wherein the island type diode TEGs comprise:
a device isolation layer pattern having a predetermined gap between adjacent active areas;
an active area pattern in the device isolation layer pattern; and
a contact pattern in the active region pattern.

17. The method according to claim 15, wherein the leakage current is related to a difference in a dimension of the active area pattern and the contact pattern.

18. The method according to claim 17, further comprising one or more second device isolation layer patterns and one or more second contact patterns having one or more dimensions greater than the value of a minimum design rule.

19. The method according to claim 17, wherein the device isolation layer pattern and the contact pattern have one or more dimensions equal to the value of a minimum design rule.

20. The method according to claim 16, wherein the contact pattern provides one contact to each active region in the active region pattern.
